(19) United States
(12) Patent Application Publication
(10) Pub. No.: US 2010/0155838 A1
(43) Pub. Date: Jun. 24, 2010

(54) TRENCH TYPE MOSFET DEVICE AND METHOD OF MANUFACTURING THE SAME

(76) Inventor: Ji-Houn Jung, Gangnam-gu (KR)

Correspondence Address: SHERR & VAUGHN, PLLC, 620 HERNDON PARKWAY, SUITE 320, HERNDON, VA, 20170, US

(21) Appl. No.: 12/643,413

(22) Filed: Dec. 21, 2009

(30) Foreign Application Priority Data
Dec. 23, 2008 (KR) 10-2008-0132389

(51) Int. Cl. H01L 27/088; H01L 21/336; H01L 29/78; H01L 21/77

(52) U.S. Cl. 257/334; 438/270; 438/589; 257/E27.06; 257/E29.262; 257/E21.41; 257/E21.598

(57) ABSTRACT

A trench type Metal Oxide Silicon Field Effect Transistor (MOSFET) device and a method of manufacturing a trench type MOSFET device. A trench type MOSFET device may include a wide-trench source contact poly which may be formed on and/or over a space between deep-trench gate polys on and/or over a trench type power MOSFET device. An electric field may be formed around a source contact poly and/or a gate poly. A relatively strong electric field may be minimized at an edge between a trench gate and a source. Leakage may be minimized and/or reliability may be maximized.

The present application claims priority under 35 U.S.C. 119 to Korean Patent Application No. 10-2008-0132389 (filed on Dec. 23, 2008) which is hereby incorporated by reference in its entirety.

### BACKGROUND

Embodiments relate to a semiconductor device and a method of manufacturing a semiconductor device. Some embodiments relate to a Metal Oxide Silicon Field Effect Transistor (MOSFET) device, which may include a trench type MOSFET device in which a wide-trench source contact poly may be formed on and/or over a space between deep-trench gate polys on and/or over a trench type power MOSFET device.

A power MOSFET device may have relatively high switching speed and/or relatively high thermal stability, may achieve a relatively large power gain with relatively high input impedance and/or may be relatively easy to use. A power MOSFET device may be widely used in various electronic devices, including a notebook PC, a battery pack, a digital camera, a desk top PC, an LCD monitor, a B/L inverter, a graphic card, and the like.

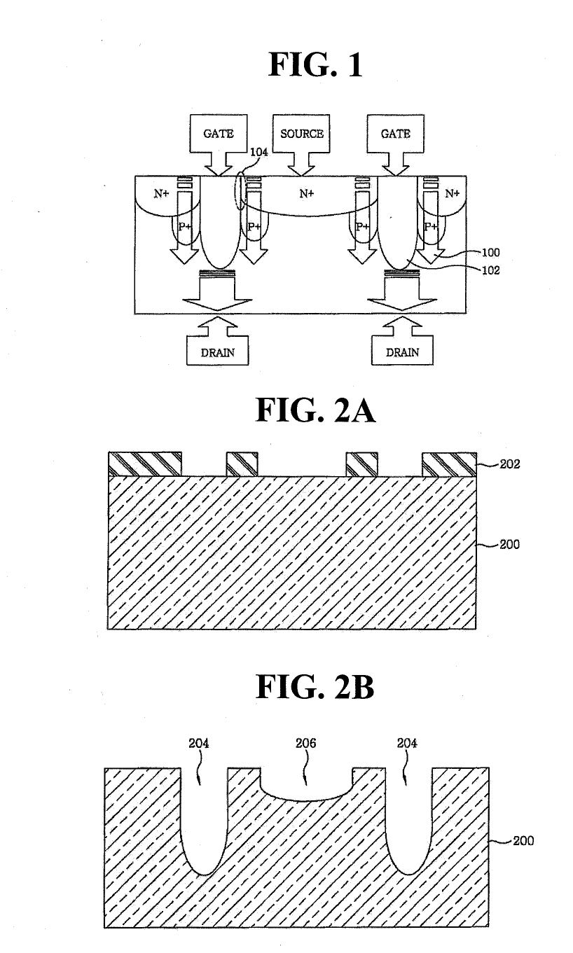

A relatively high voltage may need to be maintained and/or a relatively large current may need to be adjusted in a power MOSFET device. A trench type MOSFET device may be used in which, instead of an existing horizontal gate, a trench may be vertically formed on and/or over a substrate, an oxide film may be grown at a side surface of a trench and/or a trench may be filled with polysilicon to form a buried gate. Referring to example FIG. 1, a trench type MOSFET device may have a structure in which a gate poly may be buried on and/or over a semiconductor substrate in the form of a trench. The size of a MESA area connected to a source may be minimized in a trench type MOSFET device. Integration may be maximized.

A relatively strong electric field may be applied to a gate poly in a structure using a deep-trench gate as illustrated in FIG. 1. Current flow 100 in a MOS channel may lean to around gate poly 102. A relatively excessive current may flow in a MOS channel. Leakage may occur at edge 104 between a trench gate and a source around a surface of an active region, for example due to an excessive current flowing in a MOS channel around a gate.

Accordingly, there is a need for a MOSFET device and a method of manufacturing a MOSFET device, which may include a trench type MOSFET device in which a wide-trench source contact poly may be formed on and/or over a space between deep-trench gate polys on and/or over a trench type power MOSFET device, such that an electric field may be formed around a source contact poly and/or a gate poly, and/or may minimize a relatively strong electric field at an edge between a trench gate and a source.

### SUMMARY

Embodiments relate to a trench type Metal Oxide Silicon Field Effect Transistor device (MOSFET) device and methods of manufacturing a trench type MOSFET device. According to embodiments, a wide-trench source contact poly may be formed on and/or over a space between deep-trench gate polys on and/or over a trench type power MOSFET device. In embodiments, an electric field may be formed around a source contact poly and/or a gate poly. In embodiments, a relatively strong electric field may be minimized at an edge between a trench gate and a source.

Embodiments relate to a trench type MOSFET device. According to embodiments, a trench type MOSFET device may include one or more trench gates. In embodiments, a trench type MOSFET device may include a trench source contact between trench gates, which may have a depth relatively smaller than those of gates. In embodiments, a trench type MOSFET device may include an active region layer formed between a source contact and gates, for example by ion injection.

Embodiments relate to a method of manufacturing a trench type MOSFET device. According to embodiments, a method of manufacturing a trench type MOSFET device may include forming a trench region to form trench gates and/or a trench source contact. In embodiments, a method of manufacturing a trench type MOSFET device may include depositing and/or etching back a polysilicon film on and/or over a trench region, such that gates and/or a source contact may be formed. In embodiments, a method of manufacturing a trench type MOSFET device may include forming a photoresist mask, such that trench gates and/or a trench source contact may not be exposed. In embodiments, a method of manufacturing a trench type MOSFET device may include forming an active region layer between a source contact and gates, for example by ion injection with a photoresist mask.

According to embodiments, a wide-trench source contact poly may be formed on and/or over a space between deep-trench gate polys on and/or over a trench type power MOSFET device. In embodiments, an electric field may be formed around a source contact poly and/or a gate poly. In embodiments, a relatively strong electric field may be minimized at an edge between a trench gate and a source. In embodiments, leakage may be minimized and/or reliability may be maximized.

### DRAWINGS

Example FIG. 1 is a diagram illustrating a current flow in a trench type Metal Oxide Silicon Field Effect Transistor device.

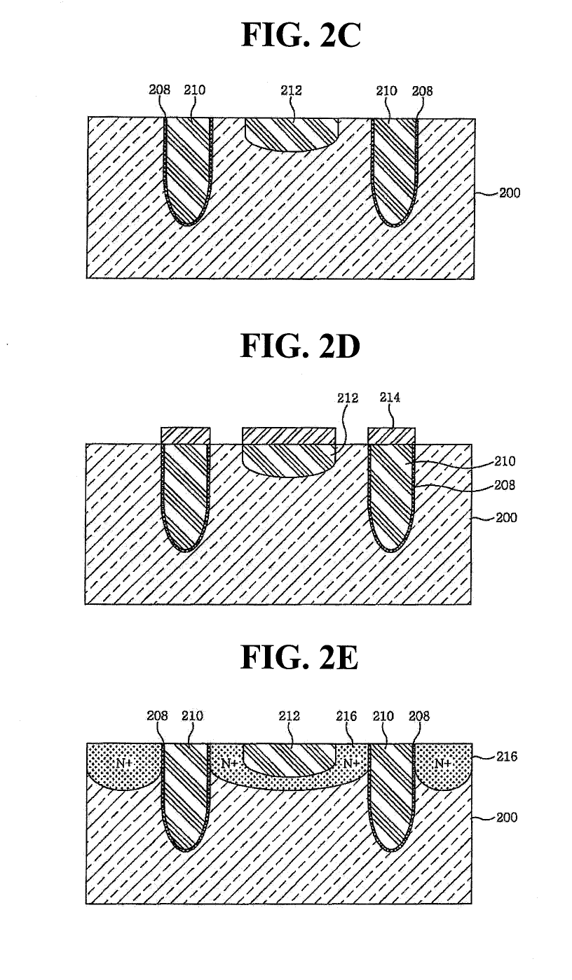

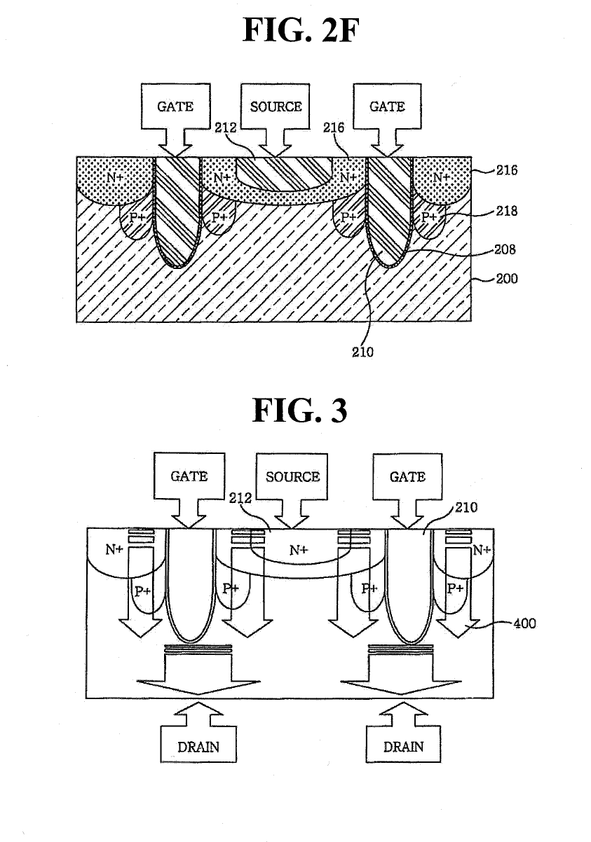

Example FIG. 2A to FIG. 2F are sectional views of a method of manufacturing a trench type Metal Oxide Silicon Field Effect Transistor device in accordance with embodiments.

Example FIG. 3 is a diagram illustrating a current flow of a trench type Metal Oxide Silicon Field Effect Transistor device in accordance with embodiments.

### DESCRIPTION

Embodiments relate to a trench type Metal Oxide Silicon Field Effect Transistor device (MOSFET) and a method of manufacturing a trench type MOSFET device. According to embodiments, a wide-trench source contact poly may be formed on and/or over a space between deep-trench gate polys on and/or over a trench type power MOSFET device. In embodiments, an electric field may be formed around a source contact poly and/or a gate poly. In embodiments, a relatively strong electric field may be formed at an edge between a trench gate and a source.

Referring to example FIG. 2A to FIG. 2F, sectional views illustrate a method of manufacturing a trench type MOSFET in accordance with embodiments. According to embodiments, a method of manufacturing a trench type MOSFET device may include a buffer gate. Referring to FIG. 2A, a photoresist film may be applied on and/or over semiconductor substrate 200. In embodiments, a photoresist film may be patterned to form a photoresist mask, such as photoresist mask 202, which may be used to etch a trench forming region.

Referring to FIG. 2B, semiconductor substrate 200 may be etching using photoresist mask 202, which may simultaneously form relatively deep trenches 204, where gate polys may be formed, and/or relatively wide trench 206, for a source contact. According to embodiments, deep trenches 204 for a gate poly and/or wide trench 206 for a source contact may be formed, for example simultaneously, by etching. In embodiments, etching may be performed using an inverse Reactive Ion Etch (RIE) lag phenomenon.

According to embodiments, a RIE lag phenomenon may indicate that a narrow trench may have a relatively low etch rate, and/or that a wide trench may have a relatively high etch rate. In embodiments, an inverse RIE lag phenomenon may indicates that a wide trench may have a relatively low etch rate, and/or that a narrow trench may have a relatively high etch rate. In embodiments, such a phenomenon may occur when etching may be performed by chemistry causing polymer deposition. In embodiments, SF₆, CF₄ and/or O₂ may be used.

According to embodiments, polymer forming species entering a feature may be condensed on and/or over a trench sidewall, as compared with etching species. In embodiments, since a feature size may be relatively small, a polymer forming species may be condensed on and/or over a trench sidewall and/or a bottom portion of a trench may be continuously etched. In embodiments, a feature size may be relatively large, an area of a trench sidewall may be relatively small, a polymer forming species may enter a bottom portion of a trench, which may cause an inverse RIE lag phenomenon such that an etch rate may be minimized. In embodiments, O₂ gas may be added such that this phenomenon may be maximized. In embodiments, deep trenches 204 for gate poly and/or wide trench 206 for a source contact may be etched, and/or may be formed simultaneously using for example an inverse RIE lag phenomenon. In embodiments, one patterning step may be eliminated and/or a manufacturing process may be relatively simplified.

Referring to FIG. 2C, gate oxide film 208 may be formed on and/or over deep trenches 204 where gate polys may be formed. According to embodiments, a polysilicon film may be deposited on and/or over a surface, which may be an entire surface, of a semiconductor substrate such that gate polys 210 and/or source contact poly 212 may be formed. In embodiments, a gate oxide film may be formed to have a thickness between approximately 200 Å and 300 Å. In embodiments, source contact poly 212 may be formed to have a thickness between approximately 4500 Å and 10000 Å.

Referring to FIG. 2D, a photoresist film may be applied on and/or over a semiconductor substrate having gate polys 210 and/or source contact poly 212. According to embodiments, a photoresist film may be patterned, such that gate polys 210 and/or source contact poly 212 may not be substantially exposed. In embodiments, photoresist mask 214 may be formed, for example to be used in ion injection.

Referring to FIG. 22, ion injection using photoresist mask 214 may be performed. According to embodiments, N+ ions 216 may be injected at opposite sides of gate polys 210. Referring to FIG. 2F, P+ ions 218 may be injected at opposite sides of gate polys 210, such that an active region may be formed. In embodiments, a trench type MOSFET device may be manufactured.

Referring to example FIG. 3, a current flow is illustrated when power may be applied to a trench type MOSFET device in accordance with embodiments. According to embodiments, power may be applied to gate polys 210, and/or an electric field may be formed around source contact poly 212 and/or around gate polys 210. In embodiments, current flow 400 from a source to a drain that may lean to gate polys 210 may be minimized. In embodiments, an excessive current may be substantially prevented from flowing in a MOS channel around gate polys 210, such that leakage at an edge between a trench gate and a source around a surface of an active region due to an excessive current flowing in a MOS channel around a gate may be minimized. In embodiments, reliability of a device may be maximized.

According to embodiments, a wide-trench source contact poly may be formed on and/or over a space between deep-trench gate polys on and/or over a trench type power MOSFET device. In embodiments, an electric field may be formed around a source contact poly and/or a gate poly. In embodiments, a relatively strong electric field at an edge between a trench gate and a source may be minimized. In embodiments, leakage may be minimized. In embodiments, reliability may be maximized.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
at least two trench gates;
a trench source contact between said at least two trench gates comprising a smaller depth relative to said at least two trench gates; and
an ion-injected active region layer between said source contact and said at least two gates.

2. The apparatus of claim 1, wherein at least one of said at least two trench gates and said source contact comprise polysilicon films.

3. The apparatus of claim 1, wherein said at least two trench gates comprise a gate oxide film having a thickness between approximately 200 Å and 300 Å.

4. The apparatus of claim 1, wherein said source contact comprises a polysilicon film having a thickness between approximately 4500 Å and 10000 Å.

5. The apparatus of claim 1, wherein said at least two trench gates, said trench source contact and said ion-injected active region layer are formed over a semiconductor substrate.

6. The apparatus of claim 1, wherein said an ion-injected active region layer comprises N+ ions.

7. The apparatus of claim 1, comprising a Metal Oxide Silicon Field Effect Transistor device.

8. The apparatus of claim 7, wherein current flow between a source and a drain that leans to at least one of said at least two trench gates is minimized when power is applied to said at least two trench gates.

9. A method comprising:
forming a trench region to form at least two trench gates and a trench source contact;
etching back a polysilicon film formed over said trench region to form said at least two gates and said source contact;
forming a photoresist mask to expose a region substantially excluding said at least two trench gates and said trench source contact; and
forming an active region layer between said source contact and said at least two gates by ion injection using said photoresist mask.

10. The method of claim 9, wherein said etching back simultaneously forms said at least two gates and said source contact.

11. The method of claim 9, wherein said source contact is formed between said at least two trench gates.

12. The method of claim 11, wherein said source contact comprises a smaller depth relative to said at lest two trench gates.

13. The method of claim 11, wherein said source contact comprises a polysilicon film.

14. The method of claim 13, where said polysilicon film comprises a thickness between approximately 4500 Å and 10000 Å.

15. The method of claim 9, wherein forming said photoresist mask comprises:
applying a photoresist film over an entire surface of a semiconductor substrate including said at least two trench gates and said source contact; and
patterning said photoresist film such that said at least two trench gates and said source contact are not substantially exposed.

16. The method of claim 9, wherein said at least two trench gates and said source contact comprise polysilicon films

17. The method of claim 9, wherein said at least two trench gates comprise a gate oxide film having a thickness between approximately 200 Å and 300 Å.

18. The method of claim 9, wherein said ion injection comprises using N+ ions.

19. The method of claim 9, comprising forming a Metal Oxide Silicon Field Effect Transistor device.

20. The method of claim 19, wherein current flow between a source and a drain that leans to at least one of said at least two trench gates is minimized when power is applied to said at least two trench gates.
